(19) United States
(12) Patent Application Publication
(10) Pub. No.: US 2017/0062652 A1
(43) Pub. Date: Mar. 2, 2017

(54) LIGHT EMITTING DEVICE, METHOD FOR MANUFACTURING LIGHT EMITTING DEVICE, AND PROJECTOR

(71) Applicant: Seiko Epson Corporation, Tokyo (JP)

(72) Inventor: Yasutaka IMAI, Suwa (JP)

(21) Appl. No.: 15/240,180

(22) Filed: Aug. 18, 2016

(30) Foreign Application Priority Data
Aug. 24, 2015 (JP) 2015-164508

(51) Int. Cl. H01L 33/06; H04N 9/31; H01L 33/10; H01S 5/343; H01L 33/30; H01L 33/00

(52) U.S. Cl. CPC H01L 33/06; H01L 33/30; H01L 33/0045; H01L 33/0012; H01L 33/10; H01L 33/0062; H01S 5/343; H04N 9/3105; H04N 9/3161

(57) ABSTRACT

A light emitting device includes an active layer capable of producing light when current is injected thereinto, a first cladding layer and a second cladding layer that sandwich the active layer, a first electrode electrically connected to the first cladding layer, and a second electrode electrically connected to the second cladding layer. The active layer forms an optical waveguide that guides the light produced in the active layer. The optical waveguide has a window section that is provided in an end portion of the optical waveguide and has a band gap wider than the band gap of the active layer. The carrier concentration of a first layer provided between the window section and the second electrode is lower than the carrier concentration of the second cladding layer.

### BACKGROUND

1. Technical Field

The present invention relates to a light emitting device, a method for manufacturing the light emitting device, and a projector.

2. Related Art

In an edge emitting device, such as a semiconductor laser, high-output light emission operation damages the light emitting end surface due to COD (catastrophic optical damage) in some cases, resulting in no light emission.

As a technique for preventing the light emitting end surface from being damaged due to COD, JP-A-2005-294748, for example, discloses a technology for disordering the quantum well structure in the vicinity of the light emitting end surface to form a window structure (window section) for suppression of light absorption in the vicinity of the light emitting end surface. JP-A-2005-294748 further discloses a method for disordering the quantum well structure in the vicinity of the light emitting end surface to form a window structure by forming a ZnO film in sputtering in the vicinity of the emitting end surface and then thermally causing Zn to undergo solid phase diffusion.

In the window structure forming method described above, it is necessary to diffuse Zn to a position deeper than the active layer (quantum well structure), and Zn also functions as a P-type dopant. In the area where Zn has been diffused, the carrier concentration is therefore higher than in the other area, so that the electrical resistivity is lower than in the other area. Current injected from electrodes therefore tends to flow through the area where Zn has been diffused, and leak current that does not contribute to laser oscillation is likely to be produced.

### SUMMARY

An advantage of some aspects of the invention is to provide a light emitting device that allows reduction in leak current and a method for manufacturing the light emitting device. Another advantage of some aspects of the invention is to provide a projector including the light emitting device.

A light emitting device according to an aspect of the invention include an active layer capable of producing light when current is injected thereinto, a first cladding layer and a second cladding layer that sandwich the active layer, a first electrode electrically connected to the first cladding layer, and a second electrode electrically connected to the second cladding layer. The active layer forms an optical waveguide that guides light, the optical waveguide has a window section that is provided in an end portion of the optical waveguide and has a band gap wider than a band gap of the active layer, and a carrier concentration of a first layer between the window section and the second electrode is lower than a carrier concentration of the second cladding layer.

In the light emitting device described above, since the carrier concentration of the first layer is lower than the carrier concentration of the second cladding layer, the electrical resistivity of the second cladding layer can be lower than the electrical resistivity of the first layer. Therefore, in the light emitting device, leak current that flows through the first layer and the window section and does not contribute to laser oscillation can be reduced as compared, for example, with a case where the carrier concentration of the first layer is higher than the carrier concentration of the second cladding layer.

In the light emitting device according to the aspect of the invention, the window section may be an area produced by diffusion of an element that belongs to a group II or XII into the active layer.

In the light emitting device described above, the diffusion of an element that belongs to the group II or XII into the active layer disorders the active layer and allows formation of the window section, the band gap of which is wider than that of the active layer.

In the light emitting device according to the aspect of the invention, the first layer may have a first portion provided between the window section and the second electrode and a second portion that forms the window section.

In the light emitting device described above, the window section can be readily formed by use of buried material regrowth, as will be described later.

In the light emitting device according to the aspect of the invention, when viewed in a direction in which the active layer and the first cladding layer are layered on each other, the optical waveguide may extend in a direction inclined with respect to a perpendicular line intersecting an end surface of the optical waveguide.

The light emitting device described above, in which no direct resonator is formed in the optical waveguide, does not allow laser oscillation of the light produced in the optical waveguide. As a result, the light emitting device allows reduction in speckle noise.

A method for manufacturing a light emitting device according to an aspect of the invention is a method for manufacturing a light emitting device in which an active layer forms an optical waveguide that guides light and the optical waveguide has a window section that is provided in an end portion of the optical waveguide and has a band gap wider than a band gap of the active layer, the method including sequentially layering a first cladding layer, the active layer, and a second cladding layer on each other, diffusing an element that belongs to a group II or XII into part of the second cladding layer and part of the active layer to convert the part of the second cladding layer into a first layer and the part of the active layer into the window section, and annealing the second cladding layer in laser annealing to increase a dopant activation rate of the second cladding layer so as to be higher than a dopant activation rate of the first layer.

In the method for manufacturing the light emitting device described above, the second cladding layer is so annealed in laser annealing that the dopant activation rate of the of the second cladding layer is so increased as to be higher than the dopant activation rate of the first layer, whereby the carrier concentration of the first layer can be lower than the carrier concentration of the second cladding layer. The manufactured light emitting device therefore allows reduction in leak current that flows through the first layer and the window section, as compared, for example, with a case where the carrier concentration of the first layer is higher than the carrier concentration of the second cladding layer.

A method for manufacturing a light emitting device according to an aspect of the invention is a method for manufacturing a light emitting device in which an active layer forms an optical waveguide that guides light and the optical waveguide has a window section that is provided in an end portion of the optical waveguide and has a band gap wider than a band gap of the active layer, the method including sequentially layering a first cladding layer, the active layer, and a second cladding layer on each other, annealing a first area of the second cladding layer in laser annealing to increase a dopant activation rate of the first area so as to be higher than a dopant activation rate of a second area of the second cladding layer, and diffusing an element that belongs to a group II or XII into the second area and a third area that is part of the active layer and overlies the second area when viewed in a direction in which the first cladding layer and the active layer are layered on each other to convert the second area into a first layer into which the element has been diffused and the third area into the window section.

In the method for manufacturing the light emitting device described above, the second cladding layer is so annealed in laser annealing that the dopant activation rate of the of the second cladding layer is so increased as to be higher than the dopant activation rate of the first layer, whereby the carrier concentration of the first layer can be lower than the carrier concentration of the second cladding layer. The manufactured light emitting device therefore allows reduction in leak current that flows through the first layer and the window section, as compared, for example, with a case where the carrier concentration of the first layer is higher than the carrier concentration of the second cladding layer.

A method for manufacturing a light emitting device according to an aspect of the invention is a method for manufacturing a light emitting device in which an active layer forms an optical waveguide that guides light and the optical waveguide has a window section that is provided in an end portion of the optical waveguide and has a band gap wider than a band gap of the active layer, the method including sequentially layering a first cladding layer, the active layer, and a second cladding layer on each other to form a layered body, etching part of the layered body to form an opening that exposes a side surface of the active layer, and burying a material that has a band dap wider than a band gap of the active layer and has a carrier concentration lower than a carrier concentration of the second cladding layer in the opening to form a first layer having the window section.

In the method for manufacturing the light emitting device described above, a material having a band gap wider than that of the active layer and a carrier concentration lower than that of the second cladding layer in the opening to form the first layer including the window section having a band gap wider than that of the active layer, whereby the carrier concentration of the first layer can be lower than the carrier concentration of the second cladding layer. The manufactured light emitting device therefore allows reduction in leak current that flows through the first layer, as compared, for example, with a case where the carrier concentration of the first layer is higher than the carrier concentration of the second cladding layer.

A projector according to an aspect of the invention includes the light emitting device according the aspect of the invention, a light modulator that modulates light outputted from the light emitting device in accordance with image information, and a projection apparatus that projects an image formed by the light modulator.

The projector described above, which includes the light emitting device according to the aspect of the invention, allows, for example, reduction in power consumption.

### BRIEF DESCRIPTION OF THE DRAWINGS

The invention will be described with reference to the accompanying drawings, wherein like numbers reference like elements.

FIG. 1 is a plan view diagrammatically showing a light emitting device according to a first embodiment.

FIG. 2 is a cross-sectional view diagrammatically showing the light emitting device according to the first embodiment.

FIG. 3 is another cross-sectional view diagrammatically showing the light emitting device according to the first embodiment.

FIG. 4 is a flowchart showing an example of a method for manufacturing the light emitting device according to the first embodiment.

FIG. 5 is a cross-sectional view diagrammatically showing one of the steps of manufacturing the light emitting device according to the first embodiment.

FIG. 6 is a cross-sectional view diagrammatically showing another of the steps of manufacturing the light emitting device according to the first embodiment.

FIG. 7 is a cross-sectional view diagrammatically showing another of the steps of manufacturing the light emitting device according to the first embodiment.

FIG. 8 is a cross-sectional view diagrammatically showing another of the steps of manufacturing the light emitting device according to the first embodiment.

FIG. 9 is a flowchart showing a variation of the method for manufacturing the light emitting device according to the first embodiment.

FIG. 10 is a cross-sectional view diagrammatically showing a variation of one of the steps of manufacturing the light emitting device according to the first embodiment.

FIG. 11 is a cross-sectional view diagrammatically showing a variation of another of the steps of manufacturing the light emitting device according to the first embodiment.

FIG. 12 is a plan view diagrammatically showing a light emitting device according to a first variation of the first embodiment.

FIG. 13 is a plan view diagrammatically showing a light emitting device according to a second variation of the first embodiment.

FIG. 14 is a plan view diagrammatically showing a light emitting device according to a second embodiment.

FIG. 15 is a cross-sectional view diagrammatically showing the light emitting device according to the second embodiment.

FIG. 16 is a flowchart showing an example of a method for manufacturing a light emitting device according to the second embodiment.

FIG. 17 is a cross-sectional view diagrammatically showing one of the steps of manufacturing the light emitting device according to the second embodiment.

FIG. 18 is a cross-sectional view diagrammatically showing another of the steps of manufacturing the light emitting device according to the second embodiment.

FIG. 19 is a cross-sectional view diagrammatically showing another of the steps of manufacturing the light emitting device according to the second embodiment.

FIG. 20 is a cross-sectional view diagrammatically showing another of the steps of manufacturing the light emitting device according to the second embodiment.

FIG. 21 is a cross-sectional view diagrammatically showing another of the steps of manufacturing the light emitting device according to the second embodiment.

FIG. 22 diagrammatically shows a projector according to a third embodiment.

### DESCRIPTION OF EXEMPLARY EMBODIMENTS

Preferable embodiments of the invention will be described below in detail with reference to the drawings. It is not intended that the embodiments described below unduly limit the contents of the invention set forth in the appended claims. Further, all configurations described below are not necessarily essential configuration requirements of the invention.

### 1. First Embodiment

### 1.1. Light Emitting Device

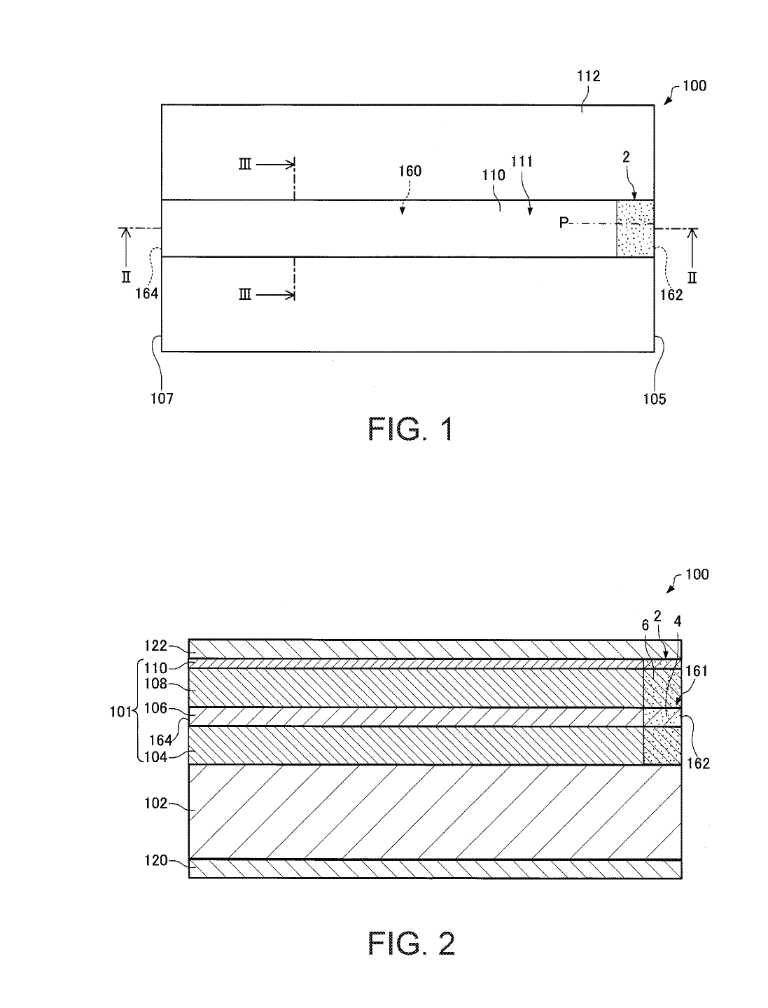

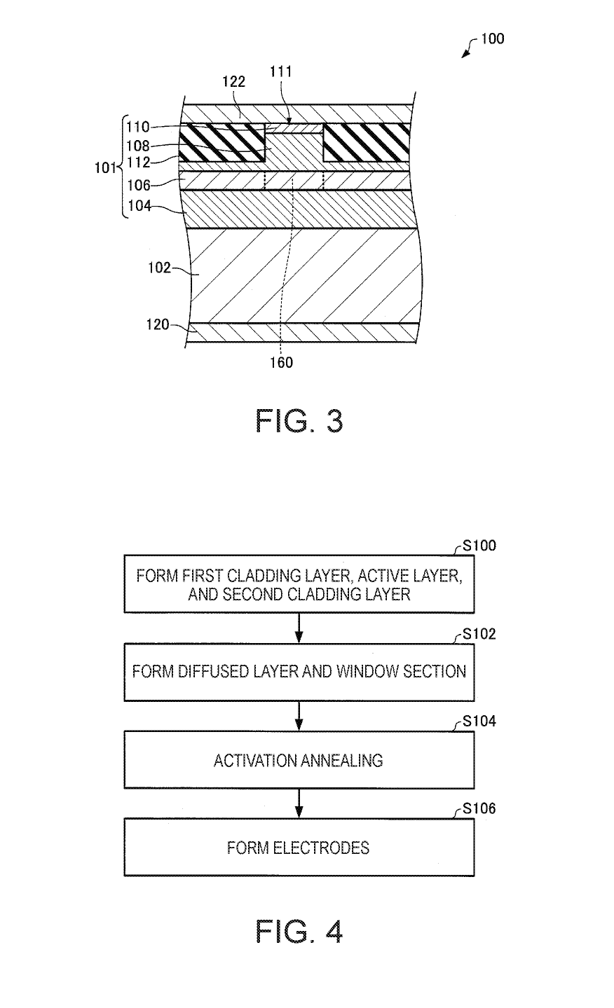

A light emitting device according to a first embodiment will first be described with reference to the drawings. FIG. 1 is a plan view diagrammatically showing a light emitting device 100 according to the first embodiment. FIG. 2 is a cross-sectional view taken along the line II-II in FIG. 1 diagrammatically showing the light emitting device 100 according to the first embodiment. FIG. 3 is a cross-sectional view taken along the line III-III in FIG. 1 diagrammatically showing the light emitting device 100 according to the first embodiment. In FIG. 1, no second electrode 122 is shown for convenience.

The light emitting device 100 includes a substrate 102, a first cladding layer 104, an active layer 106, a second cladding layer 108, a contact layer 110, an insulating layer 112, a first electrode 120, and a second electrode 122, as shown in FIGS. 1 to 3. The following description will be made of a case where the light emitting device 100 is an InGaAlP-based (red-light) semiconductor laser.

The substrate 102 is, for example, a GaAs substrate having a first conductivity type (n type, for example). A layered body 101 is formed on the substrate 102 and includes the first cladding layer 104, the active layer 106, the second cladding layer 108, the contact layer 110, the insulating layer 112, and a diffused area 2. The layered body 101 has a rectangular shape when viewed in the direction in which the first cladding layer 104 and the active layer 106 are layered on each other (hereinafter also referred to as “in a plan view”). The layered body 101 has a first side surface 105 and a second side surface 107. The first side surface 105 and the second side surface 107 are surfaces facing away from each other (surfaces parallel to each other in the example shown in FIGS. 1 to 3).

The first cladding layer 104 is provided on the substrate 102. The first cladding layer 104 is, for example, an n-type InGaAlP layer. In the first cladding layer 104, the n-type dopant can, for example, be silicon. Although not shown, a buffer layer may be formed between the substrate 102 and the first cladding layer 104. The buffer layer is, for example, an n-type GaAs, AlGaAs, or InGaP layer. The buffer layer allows improvement in crystal quality of a layer formed thereon.

The active layer 106 is provided on the first cladding layer 104. The active layer 106 has, for example, a multiple quantum well (MQW) structure in which three quantum well structures each formed of an InGaP well layer and an InGaAlP barrier layer are layered on each other. The active layer 106 may further includes a first guide layer and a second guide layer that sandwich the multiple quantum well structure. Each of the first guide layer and the second guide layer is, for example, an InGaAlP layer having a Ga composition higher than those of the first cladding layer 104 and the second cladding layer 108.

The active layer 106 is a layer capable of producing light when current is injected thereinto. Part of the active layer 106 forms an optical waveguide 160, which guides light. The light guided through the optical waveguide 160 can receive gain in the optical waveguide 160.

The optical waveguide 160 has a first end surface 162, which is provided as part of the first side surface 105, and a second end surface 162, which is provided as part of the second side surface 107. That is, the optical waveguide 160 is provided from the first side surface 105 to the second side surface 107. In a plan view, the optical waveguide 160 has a predetermined width and has a belt-like, linear shape along the direction in which the optical waveguide 160 extends. In a plan view, the optical waveguide 160 is provided in parallel to a perpendicular line P intersecting the first end surface 162 provided as part of the first side surface 105. The optical waveguide 160 is formed of the active layer 106, which guides light, and the cladding layers 104 and 108, which confine the light.

Light produced in the active layer 106 is reflected off the first end surface 162 and the second end surface 164, and the reflectance of the first end surface 162 is lower than the reflectance of the second end surface 164. Although not shown, a dielectric multilayer film may be formed on each of the side surfaces 105 and 107 of the layered body 101 in such away that the reflectance of the first end surface 162 is lower than the reflectance of the second end surface 164. In the light emitting device 100, since the reflectance of the first end surface 162 is lower than the reflectance of the second end surface 164, the first end surface 162 of the optical waveguide 160 is a light exit surface through which the light exits.

The optical waveguide 160 has a window section 4 in an end portion 161 of the optical waveguide 160. The end portion 161, which is part of the optical waveguide 160 and where the window section 4 is provided, is, for example, a portion including the light exit surface of the optical waveguide 160. The window section 4 is provided in the end portion 161 including the first end surface 162, which is the light exit surface of the optical waveguide 160.

In the example shown in FIGS. 1 to 3, the window section 4 is provided in the end portion 161 including the first end surface 162, which is the light exit surface of the optical waveguide 160, and another window section 4 may further be provided in an end portion including the second end surface 164 of the optical waveguide 160.

The window section 4 has a band gap wider than that of the active layer 106. The window section 4 can therefore suppress reabsorption of the light in the quantum well (active layer 106), whereby COD damage at the first end surface 162 of the optical waveguide 160 can be suppressed.

The window section 4 is an area produced by diffusion of an element that belongs to the group II or XII into the active layer 106. The element that belongs to the group II or XII and is diffused into the active layer 106 is, for example, zinc, magnesium, or beryllium. When any of the elements described above is diffused into the active layer 106, gallium and aluminum that form the InGaP well layer and the InGaAlP barrier layer mutually diffuse so that the order of the quantum well vanishes. That is, the quantum well structure is disordered. As a result, the band gap of the window section 4 can be wider than the band gap of the active layer 106.

The second cladding layer 108 is provided on the active layer 106. The second cladding layer 108 is, for example, an InGaAlP layer having a second conductivity type (p-type, for example). In the second cladding layer 108, the p-type dopant can, for example, be zinc or magnesium. Each of the cladding layers 104 and 108 is a layer having a band gap wider than that of the active layer 106 and having a refractive index smaller than that of the active layer 106. The cladding layers 104 and 108 sandwich the active layer 106 and has a function of suppressing carrier (electron and hole) injection and light leakage.

The window section 4 is formed by formation of a film containing an element that belongs to the group II or XII on the layered body 101 (contact layer 110) and thermal diffusion of the film. The element that belongs to the group II or XII is therefore diffused into part of the layered body 101 to form the diffused area 2. The diffused area 2 includes the window section 4 and a diffused layer 6 (example of first layer), which is formed by diffusion of the element that belongs to the group II or XII into the second cladding layer 108. In the example shown in FIGS. 1 to 3, the diffused area 2 further includes a layer formed by diffusion of the element that belongs to the group II or XII into the contact layer 110 and a layer formed by diffusion of the element that belongs to the group II or XII into the first cladding layer 104.

The diffused layer 6 is provided between the window section 4 and the second electrode 122. In the example shown in FIGS. 1 to 3, the diffused layer 6 is provided between the window section 4 and the layer formed by diffusion of the element described above into the contact layer 110. The diffused layer 6 is an area produced by diffusion of the element that belongs to the group II or XII into the second cladding layer 108. The diffused layer 6 overlies the window section 4 in a plan view. The diffused layer 6 serves as a path along which current injected from the electrodes 120 and 122 flows into the window section 4.

The carrier concentration (carrier density) of the diffused layer 6 is lower than the carrier concentration of the second cladding layer 108. Specifically, the p-type carrier concentration in the diffused layer 6 is lower than the p-type carrier concentration in the second cladding layer 108. The electrical resistivity of the second cladding layer 108 is therefore lower than the electrical resistivity of the diffused layer 6. The second cladding layer 108 therefore allows the current injected from the electrodes 120 and 122 to readily flow, as compared with the diffused layer 6. As a result, leak current that flows through the diffused layer 6 and the window section 4 and does not contribute to laser oscillation can be reduced. The carrier concentration refers to the concentration of conduction electron and hole, which contribute to electrical conduction. The carrier concentration can, for example, be determined by measurement of ECV (electrochemical capacitance voltage).

The impurity concentration of the diffused layer 6 is higher than the impurity concentration of the second cladding layer 108 by the amount corresponding to the diffused element that belongs to the group II or XII, such as Zn, and functions as the p-type dopant. Therefore, in the light emitting device 100, the dopant activation rate of the second cladding layer 108 is set to be higher than the dopant activation rate of the diffused layer 6 so that the carrier concentration of the diffused layer 6 is lower than the carrier concentration of the second cladding layer 108. The dopant activation rate of the second cladding layer 108 can be higher than the dopant activation rate of the diffused layer 6, for example, by selective annealing of the second cladding layer 108.

The contact layer 110 is provided on the second cladding layer 108. The contact layer 110 is in ohmic contact with the second electrode 122. The contact layer 110 is, for example, a p-type GaAs layer.

The contact layer 110 and part of the second cladding layer 108 form a columnar section 111, as shown in FIG. 3. The planar shape of the columnar section 111 is, for example, the same as the planar shape of the optical waveguide 160. For example, the planar shape of the columnar section 111 determines the current path between the electrodes 120 and 122. As a result, the planar shape of the optical waveguide 160 is determined. Although not shown, the side surface of the columnar section 111 may be inclined.

The insulating layer 112 is provided on the upper surface of the second cladding layer 108 and on the side surface of the columnar section 111 (around columnar section 111 in plan view). The insulating layer 112 is in contact with the side surface of the columnar section 111. The upper surface of the insulating layer 112 may be continuous with the upper surface of the contact layer 110. The insulating layer 112 is, for example, an SiN layer, an SiO₂ layer, an SiON layer, an Al₂O₃ layer, or a polyimide layer. When the insulating layer 112 is made of any of the materials described above, the current flowing through the portion between the electrodes 120 and 122 avoids the insulating layer 112 and flows through the columnar section 111 sandwiched by the portions of the insulating layer 112 that are located on opposite sides of the columnar section 111.

The insulating layer 112 has a refractive index smaller than the refractive index of the second cladding layer 108. The effective refractive index of a perpendicular cross section of the portion where the insulating layer 112 is formed is smaller than the effective refractive index of a perpendicular cross section of the portion where no insulating layer 112 is formed, that is, the portion where the columnar section 111 is formed. The light can therefore be efficiently confined in the optical waveguide 160 in the planar direction. Although not shown, the insulating layer 112 may not be provided. In this case, air that surrounds the columnar section 111 provides the same function of the insulating layer 112.

The first electrode 120 is electrically connected to the first cladding layer 104. The first electrode 120 is provided below the substrate 102. The first electrode 120 is provided on the lower surface of a layer that is in ohmic contact with the first electrode 120 (substrate 102 in the example shown in FIGS. 2 and 3). The first electrode 120 is one electrode for driving the light emitting device 100 (injecting current into active layer 106). The first electrode 120 is, for example, a laminate in which a Cr layer, an AuGe layer, an Ni layer, and an Au layer are layered on each other in this order from the side facing the substrate 102.

The second electrode 122 is electrically connected to the second cladding layer 108. In the example shown in FIGS. 1 to 3, the second electrode 122 is electrically connected to the second cladding layer 108 via the contact layer 110. The second electrode 122 is provided on the contact layer 110. In the example shown in FIG. 3, the second electrode 122 is further provided on the insulating layer 112. The second electrode 122 is the other electrode for driving the light emitting device 100 (injecting current into active layer 106). The second electrode 122 is, for example, a laminate in which a Cr layer, an AuZn layer, and an Au layer are layered on each other in this order from the side facing the contact layer 110.

In the light emitting device 100, for example, the p-type second cladding layer 108, the active layer 106, to which no impurity is doped, and the n-type first cladding layer 104 form a pin diode. When forward bias voltage for the pin diode is applied (current is injected) between first electrode 120 and the second electrode 122, recombination of electrons and holes occurs in the area that forms the optical waveguide 160 in the active layer 106. The recombination induces light emission. The produced light serves as an origin, from which stimulated emission successively occurs, whereby the intensity of the light is amplified in the optical waveguide 160. The first end surface 162 and the second end surface 164 form a resonator, and the light is reflected off the first end surface 162 and the second end surface 164 multiple times and therefore amplified. The light amplified in the optical waveguide 160 exits through the first end surface 162.

The above description has been made of the case where the light emitting device 100 is a light emitter made of an InGaAlP-based material, and the light emitting device 100 can instead be made of any material that allows formation of the optical waveguide 160. Examples of usable semiconductor materials may include AlGaN-based, GaN-based, InGaN-based, GaAs-based, AlGaAs-based, InGaAs-based, InGaAsP-based, InP-based, GaP-based, AlGaP-based, and ZnCdSe-based semiconductor materials.

In the above description, the light emitting device 100 is described as what is called a refractive-index-waveguide light emitting device in which light is confined by introduction of a difference in refractive index between the area where the insulating layer 112 is formed and the area where no insulating layer 112 is formed, that is, the area where the columnar section 111 is formed. Although not shown, the light emitting device 100 may be what is called a gain-waveguide light emitting device in which the optical waveguide 160 produced by current injection directly serves as a waveguide area instead of introduction of a refractive index difference by formation of the columnar section 111.

The light emitting device 100 has, for example, the following features.

In the light emitting device 100, the optical waveguide 160 includes the window section 4, which has a band gap wider than that of the active layer 106 and is located in the end portion 161, and the carrier concentration of the diffused layer 6 provided between the window section 4 and the second electrode 122 is lower than the carrier concentration of the second cladding layer 108. As a result, in the light emitting device 100, the electrical resistivity of the second cladding layer 108 can be smaller than the electrical resistivity of the diffused layer 6. Therefore, in the light emitting device 100, leak current that flows through the diffused layer 6 and the window section 4 and does not contribute to laser oscillation can be reduced, as compared, for example, with a case where the carrier concentration of the diffused layer 6 is higher than the carrier concentration of the second cladding layer 108.

In the light emitting device 100, the window section 4 is an area produced by diffusion of an element that belongs to the group II or XII into the active layer 106. In the light emitting device 100, the diffusion of the element that belongs to the group II or XII into the active layer 106 disorders the quantum well and allows formation of the window section 4, the band gap of which is wider than that of the active layer 106. As a result, a situation in which the quantum well reabsorbs the light in the end portion 161 of the optical waveguide 160 can be avoided, whereby COD damage in the end portion 161 of the optical waveguide 160 can be avoided.

### 1.2. Method for Manufacturing Light Emitting Device

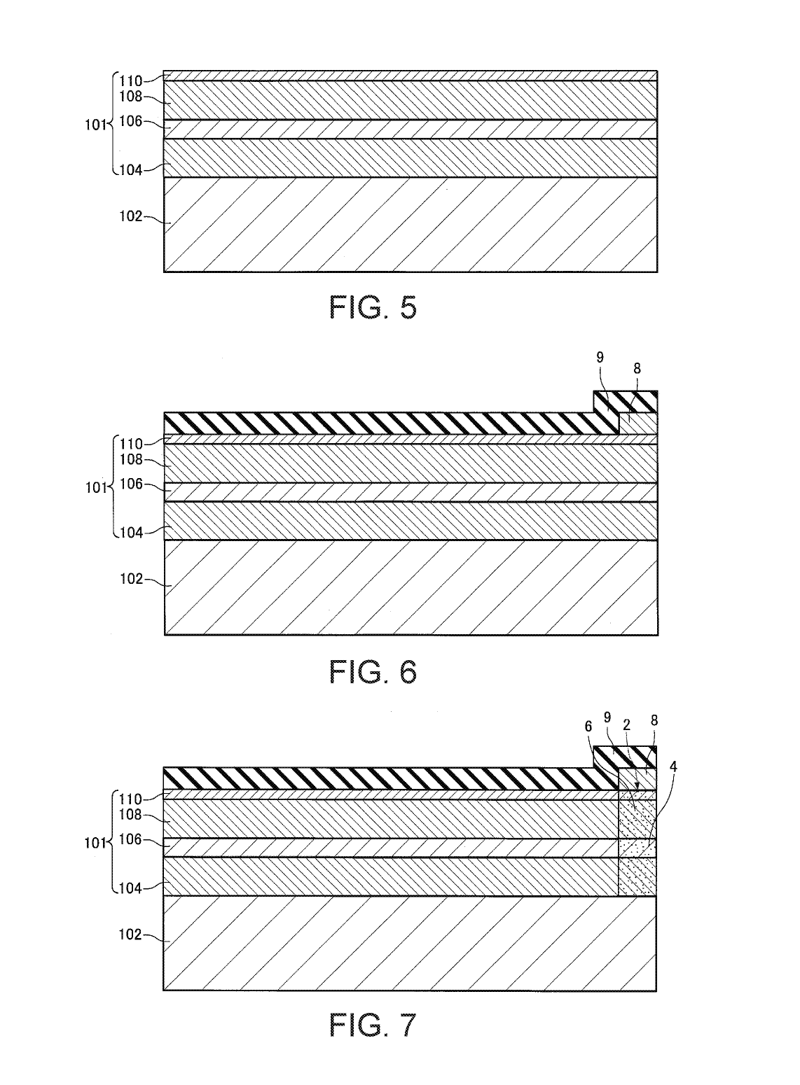

A method for manufacturing the light emitting device 100 according to the first embodiment will next be described with reference to the drawings. FIG. 4 is a flowchart showing an example of the method for manufacturing the light emitting device 100 according to the first embodiment. FIGS. 5 to 8 are cross-sectional views diagrammatically showing some of the steps of manufacturing the light emitting device 100 according to the first embodiment.

First, the first cladding layer 104, the active layer 106, and the second cladding layer 108 are layered in this order on the substrate 102 (step S100), as shown in FIG. 5.

Specifically, the first cladding layer 104, the active layer 106, the second cladding layer 108, and the contact layer 110 are formed in this order on the substrate 102 in epitaxial growth to form the layered body 101. Examples of the epitaxial growth method may include an MOCVD (metal organic chemical vapor deposition) method and an MBE (molecular beam epitaxy) method. In this process, as the n-type dopant for the n-type first cladding layer 104, for example, silicon is doped, and as the p-type dopant for the p-type second cladding layer 108 and contact layer 110, for example, magnesium is doped.

In the present step, when the layers are formed in epitaxial growth, the crystal growth is so performed that the second cladding layer 108 has a low dopant (magnesium, for example) activation rate. Specifically, the crystal growth is performed at a low temperature so that a situation in which separation of hydrogen during the crystal growth is unlikely to occur is created.

The contact layer 110 and the second cladding layer 108 are then so patterned that the columnar section 111 is formed (see FIG. 3). The patterning is performed, for example, by photolithography and etching.

The insulating layer 112 is then so formed as to cover the side surface of the columnar section 111. Specifically, an insulating material (not shown) is first formed on the second cladding layer 108 (and on contact layer 110), for example, in a CVD (chemical vapor deposition) method or an application method. The upper surface of the contact layer 110 is then exposed, for example, in an etching process. The insulating layer 112 can be formed by carrying out the steps described above. In the above description, the columnar section 111 is formed before the window section 4 is formed. The order in which the window section 4 and the columnar section 111 are formed is not limited to a specific order, and the columnar section 111 may be formed after the window section 4 is formed.

An element that belongs to the group II or XII is then diffused into part of the second cladding layer 108 and part of the active layer 106 to convert the part of the second cladding layer 108 into the diffused layer 6 and the part of the active layer 106 into the window section 4 (step S102).

First, a diffused area formation layer 8 is formed on the contact layer 110, as shown in FIG. 6. The diffused area formation layer 8 is formed on the contact layer 110, for example, in sputtering or vacuum evaporation and then patterned by photolithography and etching into a predetermined shape. The material of the diffused area formation layer 8 contains an element that belongs to the group II or XII. The material of the diffused area formation layer 8 is, for example, zinc, magnesium, beryllium, or an oxide thereof.

A coating layer 9, which covers the diffused area formation layer 8, is then formed. The material of the coating layer 9 is, for example, SiN, SiO₂, or SiON. The coating layer 9 is formed, for example, in CVD or sputtering. Formation of the coating layer 9 can prevent the elements that form the diffused area formation layer 8 from desorbing into the gas phase due to a heat treatment. Therefore, in the step of performing a heat treatment that will be described later to diffuse the element that forms the diffused area formation layer 8, the element can be efficiently diffused into the second cladding layer 108 and the active layer 106.

The element that belongs to the group II or XII and forms the diffused area formation layer 8 is then diffused by performing a heat treatment into part of the second cladding layer 108 and part of the active layer 106, as shown in FIG. 7.

The heat treatment is so performed that the element that forms the diffused area formation layer 8 reaches at least the first cladding layer 104. The heat treatment is performed, for example, at about 600° C. for about 30 minutes. In the present step, the element that forms the diffused area formation layer 8 is diffused to form the diffused area 2 including the window section 4 and the diffused layer 6. After the diffused area 2 is formed by the heat treatment, the diffused area formation layer 8 and the coating layer 9 are removed. The window section 4 and the diffused layer 6 can be formed by carrying out the steps described above.

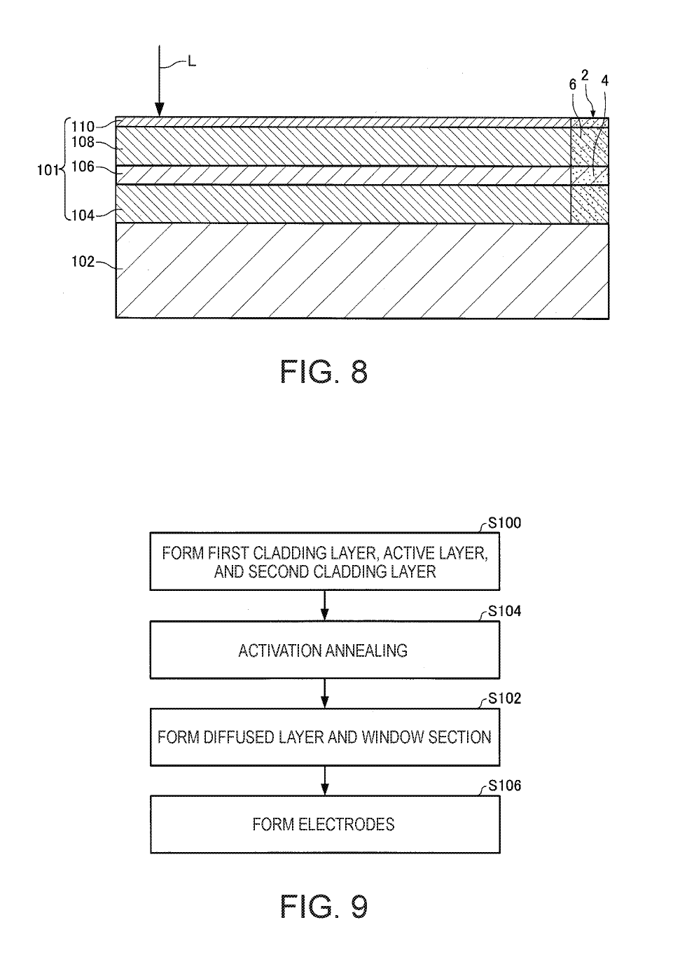

The second cladding layer 108 is then so annealed in laser annealing that the dopant activation rate of the second cladding layer 108 is higher than the dopant activation rate of the diffused layer 6 (step S104), as shown in FIG. 8.

The laser annealing is a technology that allows local annealing on the basis of a thermal effect provided by laser irradiation. A desired area can be annealed by scanning the area with a laser beam L, as shown in FIG. 8. In the present step, selective annealing (activation annealing) of the second cladding layer 108 allows separate of hydrogen in the second cladding layer 108 for activation of the dopant in the second cladding layer 108. As a result, the dopant activation rate of the second cladding layer 108 can be higher than the dopant activation rate of the diffused layer 6. The laser annealing may be performed on the entire second cladding layer 108 or only on the area that forms the optical waveguide 160 in the second cladding layer 108.

Increasing the dopant activation rate of the second cladding layer 108 so as to be higher than the dopant activation rate of the diffused layer 6 as described above allows the carrier concentration of the diffused layer 6 to be so decreased as to be lower than the carrier concentration of the second cladding layer 108.

The first electrode 120 is then formed on the lower surface of the substrate 102, and the second electrode 122 is formed on the contact layer 110 (step S106), as shown in FIG. 2. The electrodes 120 and 122 are formed, for example, in vacuum evaporation or sputtering. The order in which the electrodes 120 and 122 are formed is not limited to a specific order.

The light emitting device 100 can be manufactured by carrying out the steps described above.

The method for manufacturing the light emitting device 100 includes the step of diffusing an element that belongs to the group II or XII into part of the second cladding layer 108 and part of the active layer 106 to convert the part of the second cladding layer 108 into the diffused layer 6 and the part of the active layer 106 into the window section 4 and the step of annealing the second cladding layer 108 in laser annealing to increase the dopant activation rate of the of the second cladding layer 108 so as to be higher than the dopant activation rate of the diffused layer 6. The carrier concentration of the diffused layer 6 can therefore be lower than the carrier concentration of the second cladding layer 108. The manufactured light emitting device 100 therefore allows reduction in leak current that flows through the diffused layer 6 and the window section 4 and does not contribute to laser oscillation.

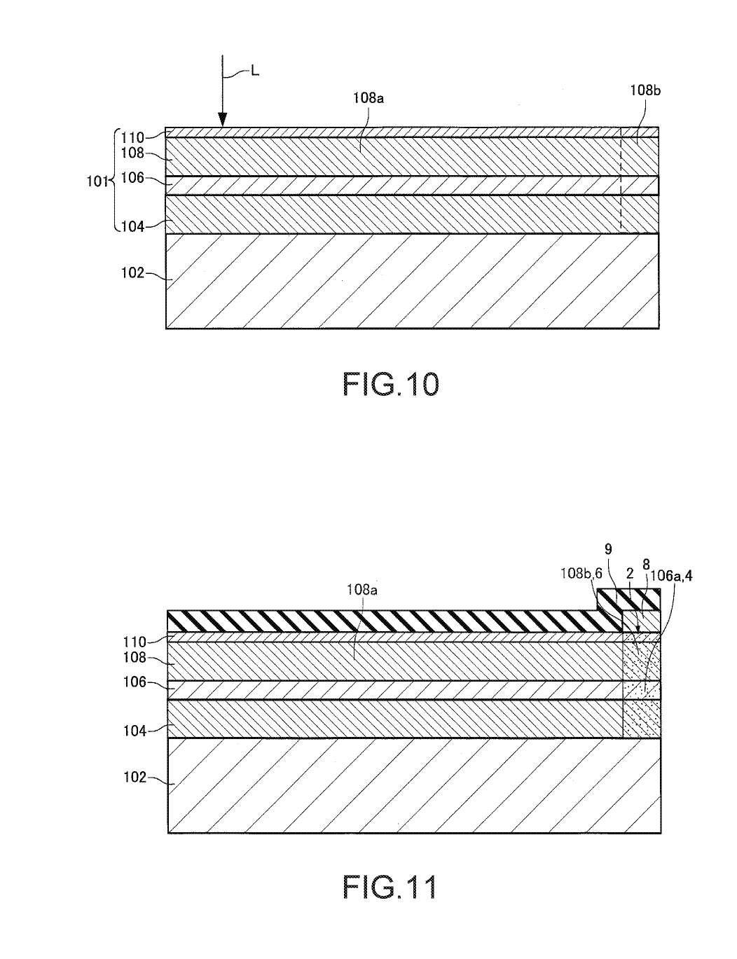

FIG. 9 is a flowchart showing a variation of the method for manufacturing the light emitting device 100 according to the first embodiment. FIGS. 10 and 11 are cross-sectional views diagrammatically showing variations of some of the steps of manufacturing the light emitting device 100 according to the first embodiment. In the following sections, points different from those in the method for manufacturing the light emitting device 100 shown in FIG. 4 and described above will be described, but the same points as those in the above method will not be described.

In the method for manufacturing the light emitting device 100 shown in FIG. 4, after the step of forming the diffused layer 6 and the window section 4 (step S102), the step of causing the second cladding layer 108 to undergo activation annealing (step S104) is carried out. Instead, after the step of causing the second cladding layer 108 to undergo activation annealing (step S104), the step of forming the diffused layer 6 and the window section 4 (step S102) may be carried out as shown in FIG. 9.

First, the first cladding layer 104, the active layer 106, and the second cladding layer 108 are layered in this order on the substrate 102 (step S100), as shown in FIG. 5.

A first area 108a of the second cladding layer 108 is then annealed in laser annealing, as shown in FIG. 10, so that the dopant activation rate of the of the first area 108a is higher than the dopant activation rate of a second area 180b of the second cladding layer 108 (step S104).

The present step allows the carrier concentration of the second area 108b of the second cladding layer 108 to be lower than the carrier concentration of the first area 108a of the second cladding layer 108. The first area 108a of the second cladding layer 108 is an area that functions as the second cladding layer 108 in the light emitting device 100. The second area 108b of the second cladding layer 108 is an area that forms the diffused layer 6.

An element that belongs to the group II or XII is then diffused into the second area 180b of the second cladding layer 108 and a third area 106a of the active layer 106, which coincides with the second area 108b in a plan view. As a result, the second area 108b of the second cladding layer 108 is converted into the diffused layer 6, and the third area 106a of the active layer 106 is converted into the window section 4 (step S102).

Specifically, the diffused area formation layer 8 is first formed on the second area 108b of the second cladding layer 108, as shown in FIG. 11. A heat treatment is then performed to diffuse the element that belongs to the group II or XII and forms the diffused area formation layer 8 into the second area 108b of the second cladding layer 108 and the third area 106a of the active layer 106. The window section 4 having a band gap wider than that of the active layer 106 and the diffused layer 6 having a carrier concentration lower than that of the second cladding layer 108 can be formed by carrying out the steps described above.

According to the method for manufacturing the light emitting device 100 according to the present variation, a light emitting device 100 that allows reduction in leak current can be manufactured, as in the case of the method for manufacturing the light emitting device 100 shown in FIG. 4 and described above.

### 1.3. Variation of Light Emitting Device

### (1) First Variation

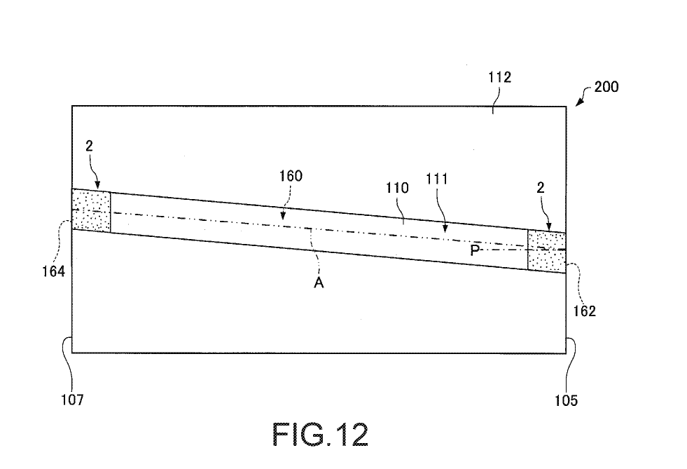

A light emitting device according to a first variation of the first embodiment will next be described with reference to the drawings. FIG. 12 is a plan view diagrammatically showing a light emitting device 200 according to the first variation of the first embodiment. In the following description, in the light emitting device 200 according to the first variation of the first embodiment, members having the same functions as those of the members that form the light emitting device 100 described above have the same reference characters and will not be described in detail.

In the light emitting device 100 described above, the optical waveguide 160 is provided in parallel to the perpendicular line P intersecting the first end surface 162 provided as part of the first side surface 105 in a plan view, as shown in FIG. 1.

In contrast, in the light emitting device 200, the optical waveguide 160 extends in a direction inclined with respect to the perpendicular line P intersecting the first end surface 162 of the optical waveguide 160 in a plan view, as shown in FIG. 12. For example, in a plan view, an imaginary straight line A, which passes through the center of the first end surface 162 and the center of the second end surface 164, is inclined with respect to the perpendicular line P, as shown in FIG. 12.

In the light emitting device 200, the light produced in the active layer 106 is so reflected off the first end surface 162 and the second end surface 164 that the reflectance of the first end surface 162 is equal to the reflectance of the second end surface 164. As a result, the light guided through the optical waveguide 160 exits through the first end surface 162 and the second end surface 164. Therefore, in the light emitting device 200, the diffused area 2 including the window section 4 and the diffused layer 6 is provided both at the first end surface 162 and the second end surface 164. COD damage at the first end surface 162 and the second end surface 164 of the optical waveguide 160 can thus be suppressed.

In the light emitting device 200, leak current that flows through the diffused layer 6 and the window section 4 can be reduced, as in the light emitting device 100 described above.

Further, in the light emitting device 200, the optical waveguide 160 extends in a direction inclined with respect to the perpendicular line P intersecting the first end surface 162 in a plan view. The light emitting device 200 can therefore prevent direct multiple reflection of the light guided through the optical waveguide 160 between the end surfaces 162 and 164. The light emitting device 200, in which no direct resonator is formed, therefore does not allow laser oscillation of the light guided through the optical waveguide 160. As a result, the light emitting device 200 allows reduction in speckle noise.

That is, the light emitting device 200 is a super luminescent diode (SLD). The SLD not only shows incoherence and a broadband speckle shape as a typical light emitting diode does but also has an optical output characteristic in which a single device can output light of about up to several hundreds of milliwatts as a semiconductor laser can.

### (2) Second Variation

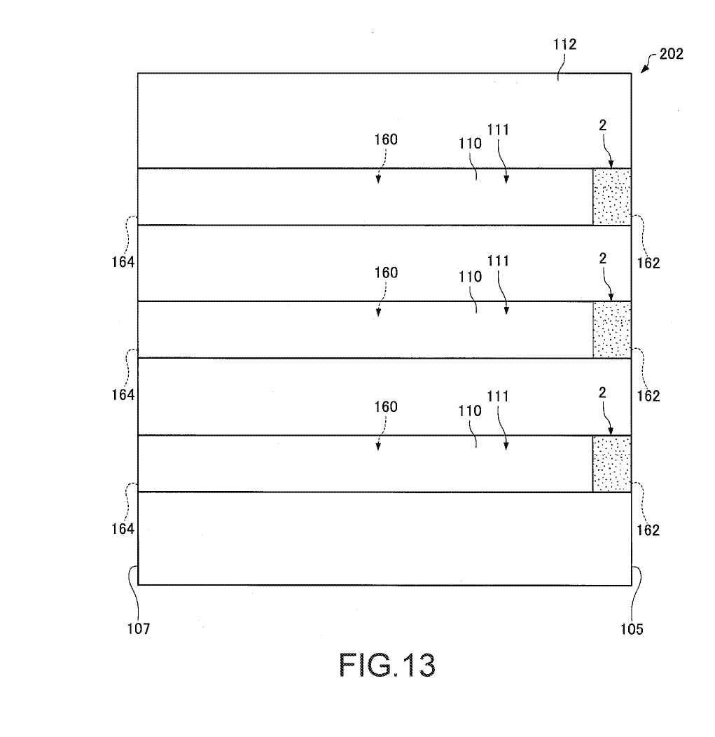

A light emitting device according to a second variation of the first embodiment will next be described with reference to the drawings. FIG. 13 is a plan view diagrammatically showing a light emitting device 202 according to the second variation of the first embodiment. In FIG. 13, the second electrode 122 is omitted for convenience.

In the following description, in the light emitting device 202 according to the second variation of the first embodiment, members having the same functions as those of the members that form the light emitting device 100 described above have the same reference characters and will not be described in detail.

The light emitting device 100 described above includes one optical waveguide 160, as shown in FIG. 1. In contrast, the light emitting device 202 includes a plurality of optical waveguides 160, as shown in FIG. 13. In the example shown in FIG. 13, the light emitting device 202 includes three optical waveguides 160.

In the light emitting device 202, leak current can be reduced, as in the light emitting device 100. Further, the light emitting device 202, in which a plurality of optical waveguides 160 are arranged, is capable of higher optical output.

### 2. Second Embodiment

### 2.1. Light Emitting Device

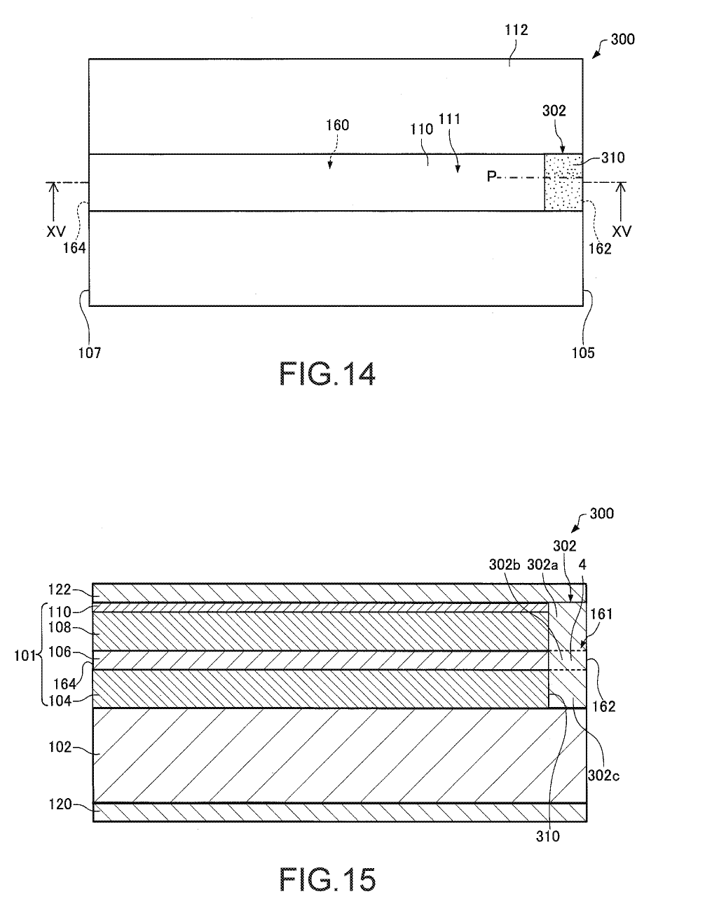

A light emitting device according to a second embodiment will next be described with reference to the drawings. FIG. 14 is a plan view diagrammatically showing a light emitting device 300 according to the second embodiment. FIG. 15 is a cross-sectional view taken along the line XV-XV in FIG. 14 diagrammatically showing the light emitting device 300 according to the second embodiment. In FIG. 14, the second electrode 122 is omitted for convenience.

In the following description, in the light emitting device 300 according to the second embodiment, members having the same functions as those of the members that form the light emitting device 100 according to the first embodiment described above have the same reference characters and will not be described.

In the light emitting device 100 described above, the window section 4 is an area produced by diffusion of an element that belongs to the group II or XII into the active layer 106, as shown in FIGS. 1 and 2.

In contrast, in the light emitting device 300, the window section 4 is formed of a buried layer 302 (example of first layer) formed by burying a material having a band gap wider than that of the active layer 106 in an opening 310 provided in the layered body 101, as shown in FIGS. 14 and 15.

The opening 310 is formed by etching part of the layered body 101. The opening 310 is formed in correspondence with the end portion 161 of the optical waveguide 160. The opening 310 is so formed as to expose at least the side surface of the active layer 106. In the example shown in FIGS. 14 and 15, the opening 310 is formed by etching part of the contact layer 110, part of the second cladding layer 108, part of the active layer 106, and part of the first cladding layer 104. As shown in FIG. 14, the opening 310 has a rectangular shape in a plan view, but not necessarily, and may instead have a circular, elliptical, or polygonal shape.

The buried layer 302 is made of a material having a band gap wider than that of the active layer 106. That is, the buried layer 302 is made of a material having an absorption edge wavelength shorter than the emitted light wavelength in the optical waveguide 160. Further, the carrier concentration of the buried layer 302 is lower than the carrier concentration of the second cladding layer 108. Specifically, the p-type carrier concentration of the buried layer 302 is lower than the p-type carrier concentration of the second cladding layer 108. The electrical resistivity of the second cladding layer 108 is therefore lower than the electrical resistivity of the buried layer 302. The second cladding layer 108 therefore allows the current injected from the electrodes 120 and 122 to readily flow as compared with the buried layer 302. As a result, leak current flowing through the buried layer 302 can be reduced.

The buried layer 302 is formed by causing a material having a band gap wider than that of the active layer 106 and a carrier concentration lower than that of the second cladding layer 108 to undergo crystal growth in the opening 310. That is, the buried layer 302 is formed on the basis of buried material regrowth. The buried layer 302 is, for example, an InAlP layer to which no impurity is doped or an InGaAlP layer to which no impurity is doped and in which the Al composition is increased.

The buried layer 302 includes a first portion 302a, which is provided between the window section 4 and the second electrode 122, and a second portion 302b, which forms the window section 4. In the example shown in FIG. 15, the buried layer 302 further includes a third portion 302c, which is provided between the window section 4 and the substrate 102.

The first portion 302a is provided between the window section 4 and the second electrode 122. The first portion 302a is a portion that is part of the buried layer 302 and overlies the window section 4 in a plan view.

The second portion 302b (window section 4) includes a portion that is part of the buried layer 302 and is connected to the active layer 106. The second portion 302b, for example, is as wide as the portion that is part of the active layer 106 and forms the optical waveguide 160, and the second portion 302b extends to the first side surface 105 of the layered body 101. The second portion 302b is part of the optical waveguide 160, and the light guided through the optical waveguide 160 exits through the second portion 302b.

According to the light emitting device 300, since the carrier concentration of the buried layer 302 between the window section 4 and the second electrode 122 (first portion 302a) is lower than the carrier concentration of the second cladding layer 108, the electrical resistivity of the second cladding layer 108 can be lower than the electrical resistivity of the buried layer 302. Therefore, in the light emitting device 300, leak current that flows through the buried layer 302 and does not contribute to laser oscillation can be reduced as compared, for example, with a case where the carrier concentration of the buried layer 302 is higher than the carrier concentration of the second cladding layer 108.

Further, in the light emitting device 300, the buried layer 302 includes the first portion 302a, which is provided between the window section 4 and the second electrode 122, and the second portion 302b, which forms the window section 4. Therefore, in the light emitting device 300, the window section 4 can be readily formed, for example, by use of buried material regrowth. Further, the formation of the window section 4 in the buried material regrowth allows formation of the window section 4 with a desired material irrespective of the materials of the active layer 106 and the cladding layers 104 and 108.

The above description has been made of the case where the light emitting device 300 is a semiconductor laser. The light emitting device 300 may instead be a super luminescent diode, as in the case of the light emitting device 200 described above and shown in FIG. 12. In this case, the speckle noise can be reduced, as in the case of the light emitting device 200.

Further, the above description has been made of the case where the light emitting device 300 includes one optical waveguide 160. The light emitting device 300 may instead include a plurality of optical waveguides 160, as in the case of the light emitting device 202 described above and shown in FIG. 13. In this case, the light emitting device 300 is capable of higher optical output, as in the case of the light emitting device 202.

### 2.2. Method for Manufacturing Light Emitting Device

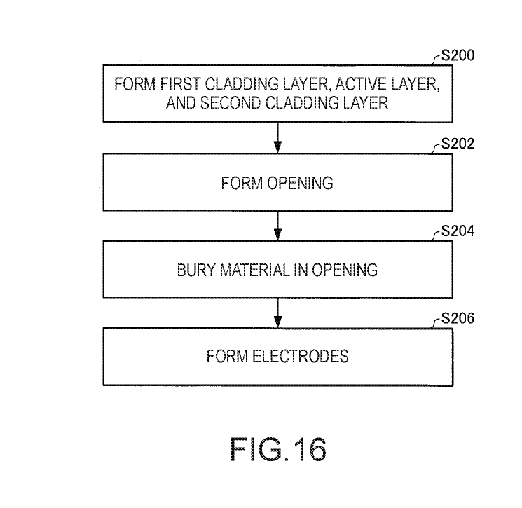

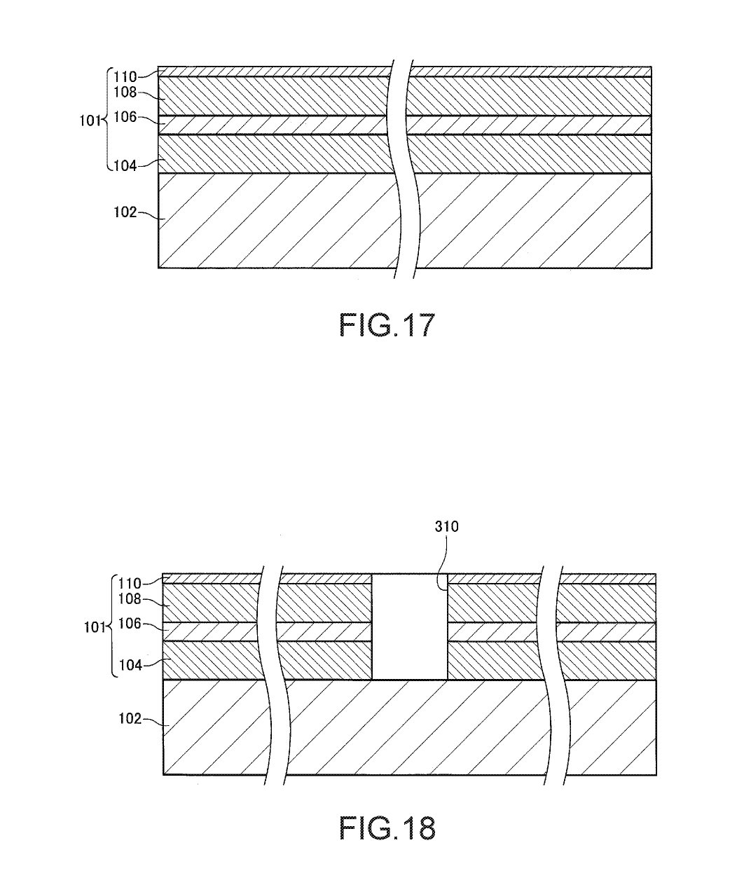

A method for manufacturing the light emitting device 300 according to the second embodiment will next be described with reference to the drawings. FIG. 16 is a flowchart showing an example of the method for manufacturing the light emitting device 300 according to the second embodiment. FIGS. 17 to 21 are cross-sectional views diagrammatically showing some of the steps of manufacturing the light emitting device 300 according to the second embodiment.

First, the first cladding layer 104, the active layer 106, and the second cladding layer 108 are layered in this order on the substrate 102 (step S200), as shown in FIG. 17. Specifically, the first cladding layer 104, the active layer 106, the second cladding layer 108, and the contact layer 110 are formed in this order on the substrate 102 in epitaxial growth to form the layered body 101. After the present step, the layered body 101 may be annealed for activation of the dopant in each of the layers.

Part of the layered body 101 is then etched to form an opening 310, which exposes the side surface of the active layer 106 (step S202), as shown in FIG. 18.

Specifically, a protective film (not shown) is first formed on the contact layer 110, and an area that is part of the formed protective film and corresponds to the opening 310 is removed. The protective film is then used as a mask and etching (dry etching, for example) is performed to form the opening 310. After the opening 310 is formed, the protective film is removed.

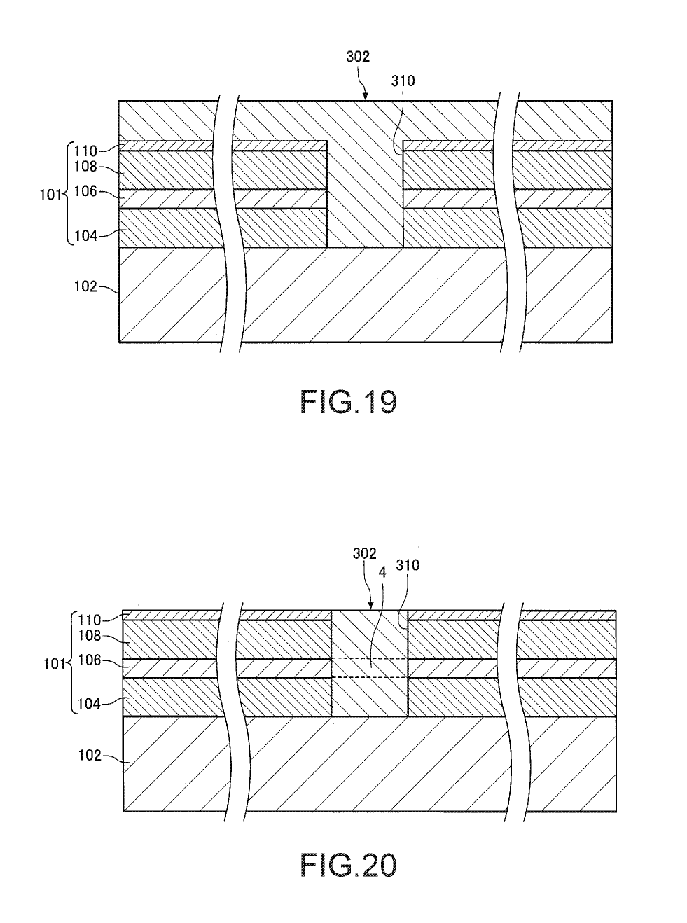

The buried layer 302, which is buried in the opening 310, is then formed in the opening 310 (step S204), as shown in FIG. 19.

The buried layer 302 is formed by causing a material having a band gap wider than that of the active layer 106 and a carrier concentration lower than that of the second cladding layer 108 to undergo crystal growth in the opening 310. The buried layer 302 is formed by regrowing the material in such a way that the material is buried in the area removed by the etching of the layered body 101 (buried material regrowth).

The formation of the buried layer 302 is performed, for example, by using MOCVD or MBE. When the buried layer 302 is, for example, an InAlP layer, MOCVD or any other method is used to cause the InAlP layer to undergo epitaxial growth in the opening 310. In this process, no dopant is doped into the InAlP layer. Part of the buried layer 302 is formed in the area outside the opening 310, such as on the contact layer 110, as shown in FIG. 19.

The buried layer 302 formed in the area outside the opening 310 is then removed, as shown in FIG. 20. The removal of the buried layer 302 formed in the area outside the opening 310 is performed, for example, by etch back operation.

The contact layer 110 and the second cladding layer 108 are then patterned to form the columnar section 111. The insulating layer 112 is then so formed as to cover the side surface of the columnar section 111. These steps are carried out in the same manner as in the method for manufacturing the light emitting device 100 described above.

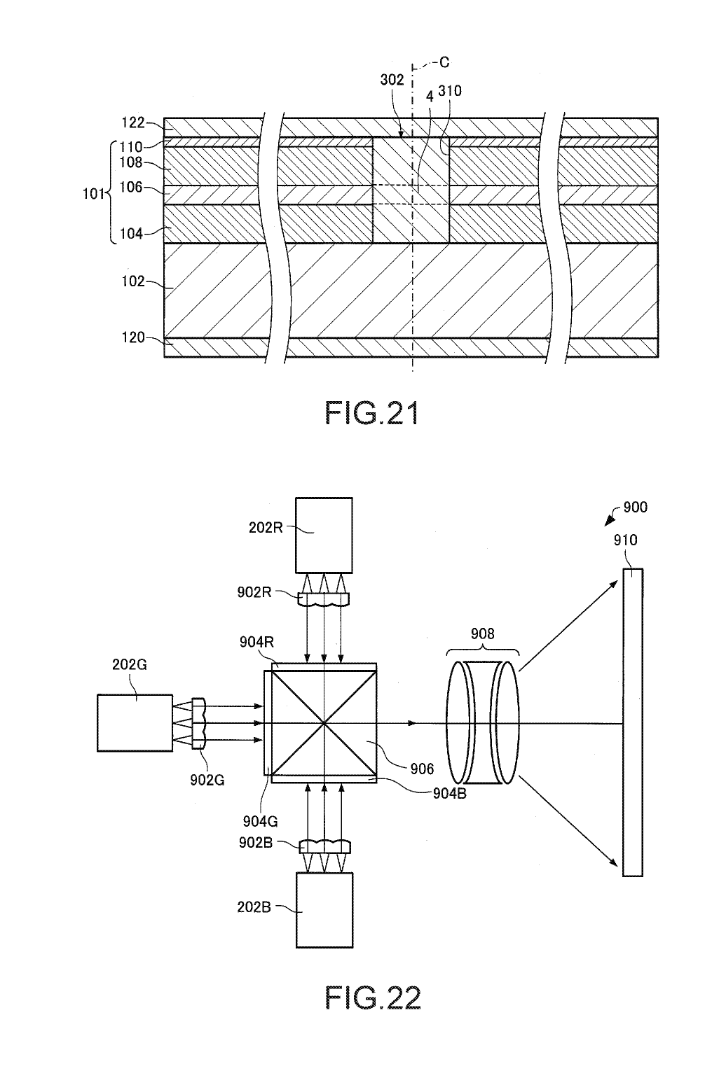

The first electrode 120 is then formed on the lower surface of the substrate 102, and the second electrode 122 is formed on the contact layer 110 (step S206), as shown in FIG. 21.

The resultant structure is then divided by cleavage into individual light emitting devices 300. For example, the cleavage is performed along the crystal surface including an imaginary straight line C so that the buried layer 302 is divided, as shown in FIG. 21.

The light emitting device 300 can be manufactured by carrying out the steps described above.

The method for manufacturing the light emitting device 300 includes the step of layering the first cladding layer 104, the active layer 106, and the second cladding layer 108 in this order on each other to form the layered body 101, the step of etching part of the layered body 101 to form the opening 310, which exposes the side surface of the active layer 106, and the step of burying a material having a band gap wider than that of the active layer 106 and a carrier concentration lower than that of the second cladding layer 108 in the opening 310 to form the buried layer 302 including the window section 4. The carrier concentration of the buried layer 302 can therefore be lower than the carrier concentration of the second cladding layer 108. A light emitting device 300 that allows reduction in leak current that flows through the buried layer 302 can therefore be manufactured.

Further, the method for manufacturing the light emitting device 300, in which the window section 4 is formed in the buried material regrowth as described above, allows the window section 4 to be readily formed and the window section 4 to be formed with a desired material irrespective of the materials of the active layer 106 and the cladding layers 104 and 108.

### 3. Third Embodiment

A projector according to a third embodiment will next be described with reference to the drawings. FIG. 22 diagrammatically shows a projector 900 according to the third embodiment.

The projector 900 includes a red light source 202R, a green light source 202G, and a blue light source 202B, which emit red light, green light, and blue light, respectively, as shown in FIG. 22. Each of the red light source 202R, the green light source 202G, and the blue light source 202B is the light emitting device according to the aspect of the invention. The following description will be made with reference to a case where the light emitting device 202 is used as the light emitting device according to the aspect of the invention. In FIG. 22, an enclosure that forms the projector 900 is omitted, and the light sources 202R, 202G, and 202B are simplified for convenience.

The projector 900 further includes lens arrays 902R, 902G, and 902B, transmissive liquid crystal light bulbs (light modulators) 904R, 904G, and 904B, and a projection lens (projection apparatus) 908.

The light fluxes emitted from the light sources 202R, 202G, and 202B are incident on the lens arrays 902R, 902G, and 902B, respectively. Each of the lens arrays 902R, 902G, and 902B causes the light fluxes emitted from the corresponding one of the light sources 202R, 202G, and 202B to gather to achieve uniform illuminance distribution. As a result, the liquid crystal light bulbs 904R, 904G, and 904B can be uniformly irradiated with light.

The light fluxes caused to gather by the lens arrays 902R, 902G, and 902B are incident on the liquid crystal light bulbs 904R, 904G, and 904B, respectively. The liquid crystal light bulbs 904R, 904G, and 904B modulate the light fluxes incident thereon in accordance with image information. The projection lens 908 then enlarges images (pictures) formed by the liquid crystal light bulbs 904R, 904G, and 904B and projects the images on a screen (display surface) 910.

The projector 900 can further include a cross dichroic prism (light combiner) 906, which combines the light fluxes outputted from the liquid crystal light bulbs 904R, 904G, and 904B with one another and guides the combined light to the projection lens 908.

The three color light fluxes modulated by the liquid crystal light bulbs 904R, 904G, and 904B are incident on the cross dichroic prism 906. The prism is formed by bonding four rectangular prisms to each other, and a dielectric multilayer film that reflects the red light and a dielectric multilayer film that reflects the blue light are so disposed as to be perpendicular to each other on the inner surfaces of the bonded prisms. The dielectric multilayer films combine the three color light fluxes with one another to form light representing a color image. The combined light is then projected by the projection lens 908, which is a projection system, on the screen 910, whereby an enlarged image is displayed.

The projector 900 can be provided with the light emitting device 202, which allows reduction in leak current. The projector 900 therefore allows, for example, reduction in power consumption.

The projector 900 has a configuration in which the light emitting device 200 is disposed immediately downstream of each of the liquid crystal light bulbs 904R, 904G, and 904B and the lens arrays 902R, 902G, and 902B are used to simultaneously perform light gathering and uniform illumination (backlight configuration). The projector 900 therefore allows reduction in light loss in the optical system and decrease in the number of parts.

In the example described above, the light emitting device 202 is used as each of the light sources 202R, 202G, and 202B of the projector 900. The light emitting device 200 may instead be used as each of the light sources of the projector 900. When the light emitting device 200, which is an SLD, is used as each of the light sources of the projector 900, speckle noise can be reduced.

Further, transmissive liquid crystal light bulb is used as the light modulator. Instead, a light bulb using no liquid crystal material or a reflective light bulb may be used. Examples of the alternative light bulbs may include a reflective liquid crystal light bulb and a digital micromirror device. Further, the configuration of the projection system is changed as appropriate in accordance with the type of the light bulb to be used.

Further, the light sources 202R, 202G, and 202B are also applicable to a light source device of a scan-type image display apparatus (projector) including a scanner that is an image forming device for displaying an image of a desired size on a display surface by scanning the screen with the light fluxes from the light sources 202R, 202G, and 202B.

In the invention, part of the configuration thereof may be omitted and the embodiments and the variations may be combined with each other to the extent that the features and advantageous effects described in the present application are maintained.

The invention encompasses substantially the same configuration as the configuration described in any of the embodiments (for example, a configuration having the same function, using the same method, and providing the same result or a configuration having the same purpose and providing the same effect). Further, the invention encompasses a configuration in which an inessential portion of the configuration described in any of the embodiments is replaced. Moreover, the invention encompasses a configuration that provides the same advantageous effect as that provided by the configuration described in any of the embodiments or a configuration that can achieve the same purpose as that achieved by the configuration described in any of the embodiments. Further, the invention encompasses a configuration in which a known technology is added to the configuration described in any of the embodiments.

The entire disclosure of Japanese Patent Application No. 2015-164508, filed Aug. 24, 2015 is expressly incorporated by reference herein.

What is claimed is:

1. A light emitting device comprising:
an active layer capable of producing light when current is injected thereinto;
a first cladding layer and a second cladding layer that sandwich the active layer;
a first electrode electrically connected to the first cladding layer; and
a second electrode electrically connected to the second cladding layer,
wherein the active layer forms an optical waveguide that guides light,
the optical waveguide has a window section that is provided in an end portion of the optical waveguide and has a band gap wider than a band gap of the active layer, and
a carrier concentration of a first layer between the window section and the second electrode is lower than a carrier concentration of the second cladding layer.

2. The light emitting device according to claim 1, wherein the window section is an area produced by diffusion of an element that belongs to a group II or XII into the active layer.

3. The light emitting device according to claim 1, wherein the first layer has a first portion provided between the window section and the second electrode and a second portion that forms the window section.

4. The light emitting device according to claim 1, wherein when viewed in a direction in which the active layer and the first cladding layer are layered on each other, the optical waveguide extends in a direction inclined with respect to a perpendicular line intersecting an end surface of the optical waveguide.

5. A method for manufacturing a light emitting device in which an active layer forms an optical waveguide that guides light and the optical waveguide has a window section that is provided in an end portion of the optical waveguide and has a band gap wider than a band gap of the active layer, the method comprising:
sequentially layering a first cladding layer, the active layer, and a second cladding layer on each other;
diffusing an element that belongs to a group II or XII into part of the second cladding layer and part of the active layer to convert the part of the second cladding layer into a first layer and the part of the active layer into the window section; and
annealing the second cladding layer in laser annealing to increase a dopant activation rate of the second cladding layer so as to be higher than a dopant activation rate of the first layer.

6. A method for manufacturing a light emitting device in which an active layer forms an optical waveguide that guides light and the optical waveguide has a window section that is provided in an end portion of the optical waveguide and has a band gap wider than a band gap of the active layer, the method comprising:
sequentially layering a first cladding layer, the active layer, and a second cladding layer on each other;
annealing a first area of the second cladding layer in laser annealing to increase a dopant activation rate of the first area so as to be higher than a dopant activation rate of a second area of the second cladding layer; and
diffusing an element that belongs to a group II or XII into the second area and a third area that is part of the active layer and overlies the second area when viewed in a direction in which the first cladding layer and the active layer are layered on each other to convert the second area into a first layer into which the element has been diffused and the third area into the window section.

7. A method for manufacturing a light emitting device in which an active layer forms an optical waveguide that guides light and the optical waveguide has a window section that is provided in an end portion of the optical waveguide and has a band gap wider than a band gap of the active layer, the method comprising:
sequentially layering a first cladding layer, the active layer, and a second cladding layer on each other to form a layered body;
etching part of the layered body to form an opening that exposes a side surface of the active layer; and
burying a material that has a band dap wider than a band gap of the active layer and has a carrier concentration lower than a carrier concentration of the second cladding layer in the opening to form a first layer having the window section.

8. A projector comprising:
the light emitting device according to claim 1;
a light modulator that modulates light outputted from the light emitting device in accordance with image information; and
a projection apparatus that projects an image formed by the light modulator.

9. A projector comprising:
the light emitting device according to claim 2;
a light modulator that modulates light outputted from the light emitting device in accordance with image information; and
a projection apparatus that projects an image formed by the light modulator.

10. A projector comprising:
the light emitting device according to claim 3;
a light modulator that modulates light outputted from the light emitting device in accordance with image information; and
a projection apparatus that projects an image formed by the light modulator.

11. A projector comprising:
the light emitting device according to claim 4;
a light modulator that modulates light outputted from the light emitting device in accordance with image information; and
a projection apparatus that projects an image formed by the light modulator.
